(19) United States
(12) Patent Application Publication
(10) Pub. No.: US 2026/0190278 A1
(43) Pub. Date: Jul. 2, 2026

(54) ARC-RESISTANT LOUVERS ASSEMBLY APPLIED TO A VENTILATION SYSTEM OF AN ELECTRICAL ENCLOSURE

(71) Applicant: WEG DRIVES & CONTROLS – AUTOMAÇÃO LTDA, Andar (BR)

(72) Inventors: Elvis ARNOLDO BUGS DÖRR, Jaraguá do Sul (BR); Joable ANDRADE ALVES, Jaraguá do Sul (BR); Allan DIEGO MAFFEZZOLLI, Jaraguá do Sul (BR); Walter JONY COELHO THIEL, Jaraguá do Sul (BR); Jackson RICARDO LINO, Jaraguá do Sul (BR); Itamar FERNANDES SOARES, Joinville (BR)

(21) Appl. No.: 19/131,120

(22) PCT Filed: Dec. 29, 2022
(86) PCT No.: PCT/BR2022/050529

§ 371 Date: May 19, 2025

(51) Int. Cl. H05K 7/20

(52) U.S. Cl. CPC H05K 7/20145

(57) ABSTRACT

The present invention relates to electrical systems and equipment used thereof. Further, the present invention provides a louvers assembly applied to a ventilation system of an electrical enclosure, wherein the louvers assembly comprises a fixed frame. The fixed frame is attached to a ventilation aperture in the wall of the ventilation input region. The louvers assembly further comprises one or more louvers, wherein each end of each louver is attached to a connecting piece that connects the fixed frame to a guide of the louvers assembly. The louvers assembly further comprises a spring system attached to the top side of the frame. The louvers assembly further comprises a locking mechanism arranged at the uppermost louver of the one or more louvers.

### TECHNICAL FIELD

The present invention relates to electrical systems and equipment used thereof. Specifically, the present invention relates to an arc-resistant louvers assembly applied to improve safety and redirect debris, flames, plasma and/or gases from the shock wave of an arc fault explosion in frequency inverters of AC motors.

### BACKGROUND

Medium-voltage drives (also called VFD's or variable frequency drives) are adjustable speed drives used to control the torque and speed of medium-voltage AC motors. These drives are abundantly utilized in large industrial facilities, such as wastewater plants, petrochemical, oil and gas, mining, food and drug, and general manufacturing.

A so-called medium voltage is a voltage up to approximately 15 kV. In this context, most medium voltage drives can be categorized as voltage source inverter (VSI) drives, which output is an adjustable three-phase AC voltage.

It should be noted that the medium voltage drives common in large industrial facilities contain a plurality of interconnected power components operating in tandem. Hence, the risks associated with operating and maintaining such complex electrical equipment should not be overlooked.

Among the main risks offered by this equipment, the arc fault explosion, or arc flash, stands out as one of the most harmful to workers, due to the large amount of energy released and the high temperatures generated by this phenomenon. Specifically, an arc fault explosion is a dangerous condition caused by an electrical arc, due to either a phase-to-ground or a phase-to-phase fault. An arc fault explosion event releases a large amount of energy in the form of thermal heat, toxic fumes, pressure and sound waves, blinding light and explosions that can cause serious injuries to the operators. Moreover, the behavior of an electric arc in a three-phase system is considered to be chaotic, as it involves a rapid and irregular change in the arc geometry due to convection, plasma jets and electromagnetic forces.

Accordingly, nowadays it becomes even more necessary to develop arc-resistant technologies in order to mitigate the risk of injury with electrical equipment, protecting personnel and equipment from arc fault explosion events occurring in electrical panels comprising medium voltage drives.

For example, there are some prior art documents that use safety ventilation arrangements in case of excessive pressure or fire due to electrical defects taking place in housings or cabinets of electrical panels with medium voltage drives. However, there are still some deficiencies in such arrangements.

One exemplary system incorporating arc-resistant technology in an electrical module enclosure is discussed in document U.S. Pat. No. 10,297,986B2. Said document discloses an arc-resistant electrical enclosure including an arresting system that permits forced-air cooling of the interior region to occur during ordinary operation of the enclosure while resisting the flow of hot gases, plasma, and flames to the exterior of the electrical enclosure in an arc event or other event. The proposed arresting system includes a louver apparatus and a cover apparatus that work in conjunction to resist the flow of gases, plasma, and flames to the exterior of the cabinet in an arc event. As stated by said document, the louver apparatus and the cover apparatus (a fire blocking plane) need to work together in order to resist the debris and flames from an arc fault explosion. A drawback of said document is that the mechanism's triggering is direct, that is, the shock wave and the increase in pressure coming from the explosion impinge directly on the louvers and there are no secondary means for activation of the system. In this way, the flames and debris pass through the inertia of the louvers, when changing from an open state to a closed state, since the explosion time is around 10 ms. Moreover, the referred document utilizes additional protection which is formed of an aluminum honeycomb that includes a coating situated in front of the louvers to prevent flames from traveling therethrough.

Further, document U.S. Pat. No. 9,6097,69 B2 discloses a system including an enclosure having a ventilation opening and an isolation assembly. The isolation assembly includes a deformable portion and a blocking portion. The blocking portion is capable of substantially blocking the ventilation opening with a blocking surface. Hence, the arc-resistant mechanism used in said document provides a metal sheet that will plastically deform and block the ventilation opening of said electrical enclosure in an arc fault explosion event.

Finally, document EP 2 918 154 B1 illustrates in FIG. 3 an embodiment of air intake louvers 300 for a power supply enclosure having an arc fault path. Nevertheless, this arc-resistant mechanism is directly triggered by the arc explosion event coming from the inside of the electrical enclosure, which does not properly prevent the flames and debris from escaping.

### SUMMARY

The present invention comes from the need in the industry to develop an electrical panel with a medium voltage drive having arc-resistant features. Specifically, the present invention discloses a ventilation system that in normal operation is cooling the electrical components inside the panel and at the moment of an arc fault explosion, has its ventilation input closed by the action of the explosion itself, thus providing greater safety to nearby people and equipment. Hence, it is an object of the present invention to provide a louvers assembly that will automatically close using the overpressure and the shock wave from an arc fault explosion.

In this sense, in one embodiment, the present invention provides a louvers assembly applied to a ventilation system of an electrical enclosure, wherein the louvers assembly comprises a fixed frame. The fixed frame is attached to a ventilation aperture in the wall of the ventilation input region. The louvers assembly further comprises one or more louvers, wherein each end of each louver is attached to a connecting piece that connects the fixed frame to a guide of the louvers assembly. The louvers assembly further comprises a spring system attached to the top side of the frame. The louvers assembly further comprises a locking mechanism arranged at the uppermost louver of the one or more louvers.

Additionally, the invention also provides a ventilation system for use in an electrical enclosure, in which the ventilation system includes an arc-resistant louvers assembly in accordance with an embodiment of the present invention.

Moreover, the present invention provides an electrical enclosure comprising an arc-resistant louvers assembly in accordance with an embodiment of the present invention.

### BRIEF DESCRIPTION OF THE DRAWINGS

In the drawings:

FIG. 1 shows a perspective view of an exemplary electrical enclosure comprising electrical equipment and a ventilation system therewithin in accordance with an embodiment of the present invention;

FIG. 2 shows a side view of a ventilation system within the electrical enclosure in accordance with an embodiment of the present invention;

FIG. 3A presents a perspective view of a louvers assembly in an open state in accordance with an embodiment of the present invention;

FIG. 3B presents a side view of a louvers assembly in an open state in accordance with an embodiment of the present invention;

FIG. 4A presents a perspective view of a louvers assembly in a closed state in accordance with an embodiment of the present invention;

FIG. 4B presents a side view of a louvers assembly in a closed state in accordance with an embodiment of the present invention;

FIG. 5A shows a perspective view of a louvers assembly with a horizontal flap in an open state in accordance with an embodiment of the present invention;

FIG. 5B shows a side view of a louvers assembly with a horizontal flap in an open state in accordance with an embodiment of the present invention;

FIG. 6A shows a perspective view of a louvers assembly with a horizontal flap in a closed state in accordance with an embodiment of the present invention;

FIG. 6B shows a side view of a louvers assembly with a horizontal flap in a closed state in accordance with an embodiment of the present invention;

FIG. 7A shows a perspective view of a louvers assembly with an inclined flap in an open state in accordance with an embodiment of the present invention;

FIG. 7B shows a side view of a louvers assembly with an inclined flap in an open state in accordance with an embodiment of the present invention;

FIG. 8A presents a perspective view of a louvers assembly with an inclined flap in a closed state in accordance with an embodiment of the present invention;

FIG. 8B presents a side view of a louvers assembly with an inclined flap in a closed state in accordance with an embodiment of the present invention;

FIG. 9A presents a sectional view of a spring system and the locking mechanism in an open state in accordance with an embodiment of the present invention;

FIG. 9B presents a sectional view of a spring system and the locking mechanism in a closed state in accordance with an embodiment of the present invention.

### DETAILED DESCRIPTION

In the following description, for the purpose of explanation, numerous specific details are set forth to provide a thorough understanding of the present disclosure. It will be apparent, however, that embodiments may be practiced without these specific details. Embodiments are disclosed in sections according to the following outline:
As described herein, an electrical “enclosure” (or “cabinet”) should be interpreted as the structure of an electrical panel comprising a medium voltage drive with a plurality of interconnected power components operating in tandem therewithin.

In addition, the expressions “flames”, “fire”, “fumes”, “gases”, “shock wave”, “expansion wave”, “debris”, among others, are generally used to refer to the products or outcomes from the arc fault explosion and should be interpreted in a broad manner rather than a particular one.

Often, electrical systems operating within these electrical enclosures are subject to a high-risk phenomenon commonly known as arc flash or arc fault. Several situations can Cause an arc flash: bad contact, insulation depreciation, equipment defects, human errors (bad design and installation, inadequate maintenance), among others.

In closed configurations, as in such enclosures, when an arc flash event occurs, the energy in the form of a shock wave caused by the explosion tends to propagate through the interior of the panel until reaching openings in the device, in general, the openings in the ventilation system.

Therefore, the present invention presents an arc-resistant louvers assembly positioned in the ventilation system of an electrical enclosure, wherein, under normal operating conditions, it contributes to the forced ventilation process promoted by the ventilation system's fans, dissipating heat and cooling the internal components of the enclosure, and at the moment of the arc flash (explosion), the louvers assembly is closed using its own energy of the explosion in the form of a shock wave caused by the melting of metals. Additionally to the closing of the louvers, covering the ventilation input of the ventilation system, the debris and gases produced by the explosion are redirected to a safe region (ventilation output) by the louvers assembly scheme instead of moving to some critical component or even to the operators.

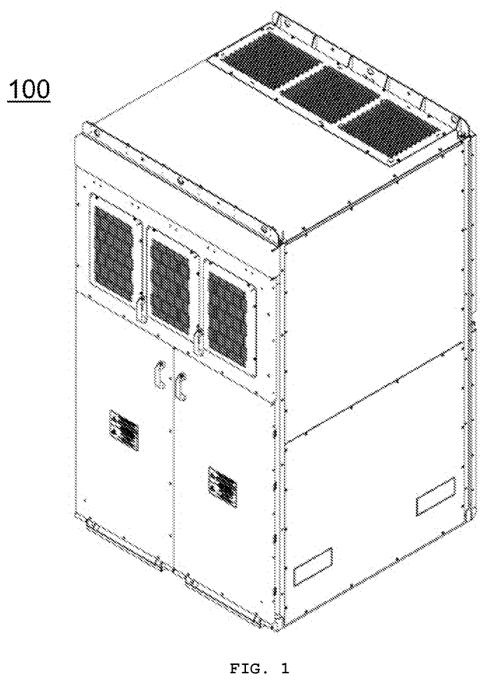

In this sense, FIG. 1 reveals an electrical enclosure 100 according to an embodiment of the present invention.

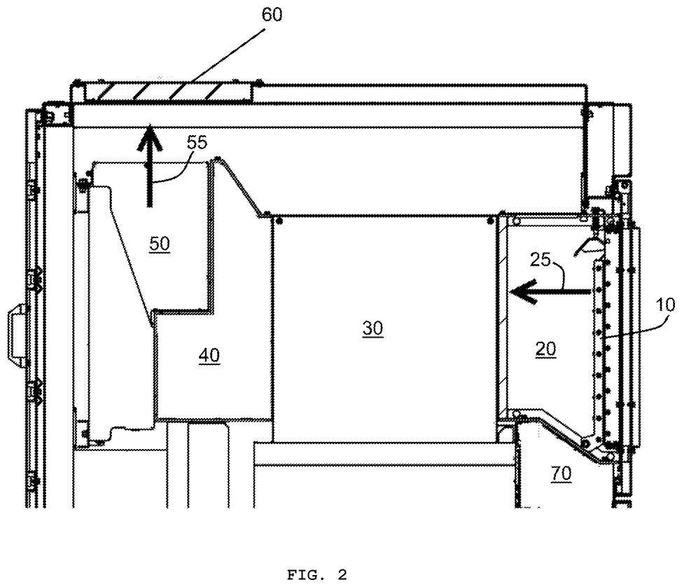

A ventilation system comprised in an electrical enclosure 100 of FIG. 1 is depicted in FIG. 2 in an exemplary embodiment in which such system is arranged in the upper region of the enclosure. Ventilation systems play a very important role in electrical panels since its electrical components, operating in a confined environment, need an adequate mechanism that will constantly remove the heat produced by them.

The ventilation system of FIG. 2 comprises a louvers assembly 10 attached to a ventilation aperture in the wall of the enclosure 100 and arranged within a ventilation input region 20 through which air flows in the input direction 25 to cool the system under normal operating conditions. The ventilation system further comprises a heatsink 30 for absorbing excessive heat, a canalization 40, and fans 50 through which air flows in the output direction 55 to the ventilation output 60 under normal operating conditions. Further, as can be exemplary seen in FIG. 2, when the electrical enclosure undergoes an arc explosion event, the shock wave produced propagates from a downstream region 70 situated immediately before the ventilation input region 20 in which the louvers assembly 10 is situated.

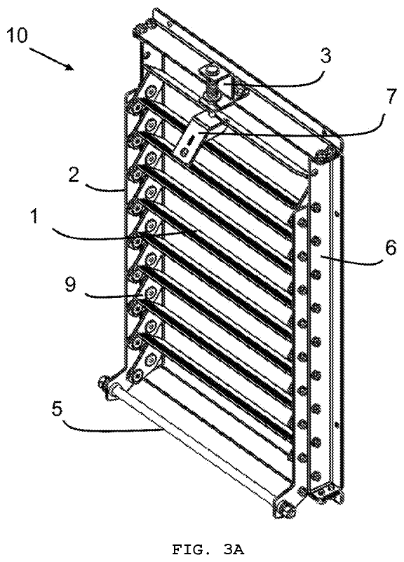

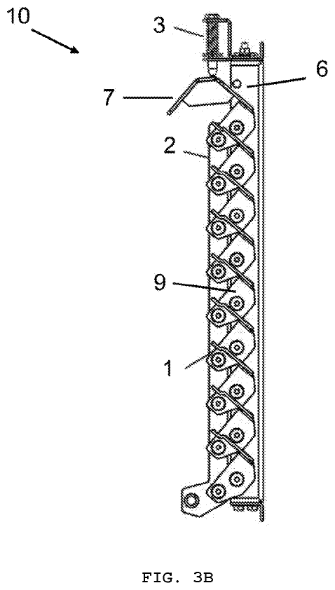

Referring now to FIGS. 3A and 3B, it is disclosed a louvers assembly 10 of the exemplary embodiment of FIG. 2 in an open state. The louvers assembly 10 comprises a fixed frame 6 and one or more louvers 1, the fixed frame 6 being attached to a ventilation aperture in the wall of the ventilation input region 20. Each end of each louver 1 being attached to a connecting piece 9 that connects the fixed frame 6 to a guide 2 of the louvers assembly 10, wherein the guide 2 is axially movable, thereby allowing the one or more louvers H to simultaneously rotate altogether upon changing from an open state to a closed state during an arc fault event.

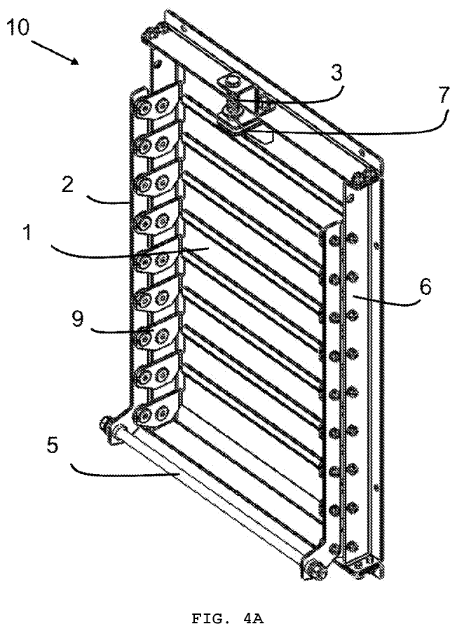

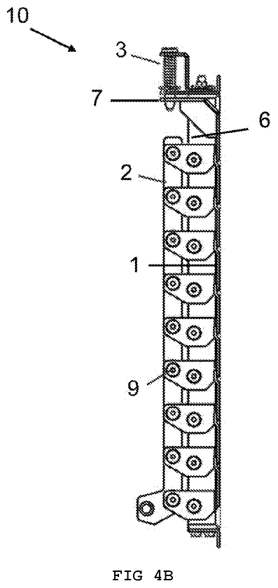

The louvers assembly 10 further comprises a spring system 3 attached to the top side of the frame 6 and a locking mechanism 7 arranged at the uppermost louver 1 of the one or more louvers 1. The spring system 3 and the locking mechanism 7 together are configured to secure and maintain the louvers 1 in a closed state, as depicted in FIGS. 4A and 4B when an arc fault event occurs.

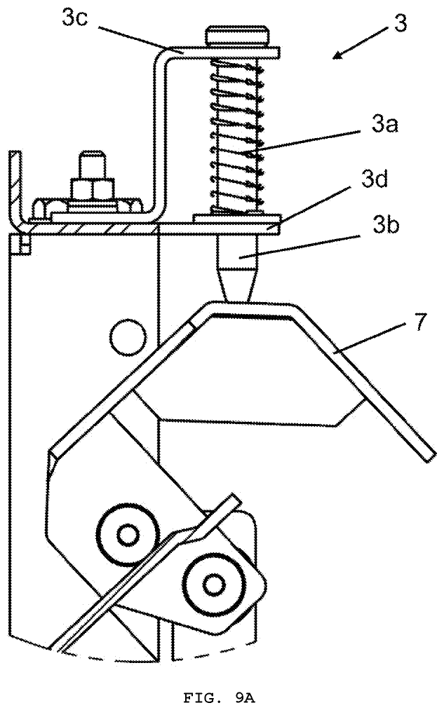

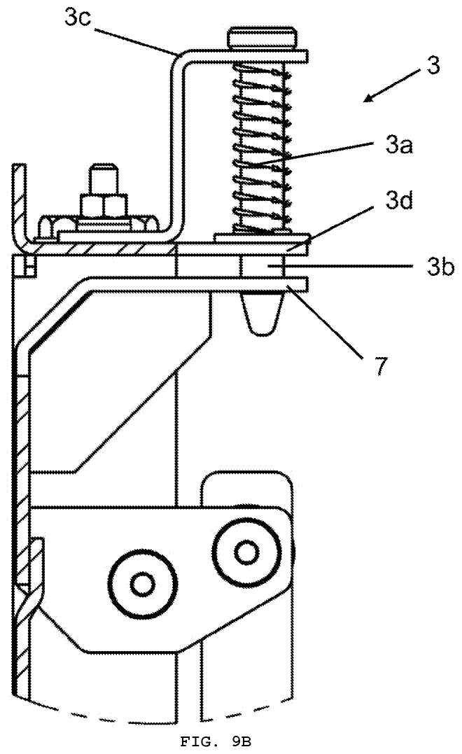

The spring system 3, as seen in FIGS. 3A to 8B and yet in more detail in FIGS. 9A and 9B, includes a pin 3b placed within a spring 3a, the pin 3b being connected at its upper portion to a first shaped plate 3c with a foldable profile and at a lower portion to a second shaped plate 3d such that the pin 3b passes through concentric holes of the plates 3c, 3d. The plates 3c, 3d forming a U-shaped profile securing the pin 3b, and the spring 3a being contained between the first shaped plate 3c and the second shaped plate 3d. Preferably, between the spring 3a and the second shaped plate 3d there is a washer. At its lower portion, the pin 3b is provided with a protrusion having a rounded tip configured to pass through the holes of the second shaped plate 3d and the locking mechanism 7. When the louvers 1 move from the open state to the closed state, it will activate the spring movement and the spring 3a will recoil and then return to its extended configuration when the rounded tip of the pin 3b reaches a groove, or hole relief, in the locking mechanism 7 before the protrusion passes through the hole located in the distal portion of the locking mechanism 7, locking the entire assembly and preventing that the louvers 1 open again due to gravity or any other forces that can happen induced by the arc fault explosion.

Moreover, the louvers assembly 10 disclosed in FIGS. 3A, 3B, 4A and 4B further comprises a rod 5 connected at each end to one of the guides 2. The rod 5 acts as a driving device since it is configured to trigger the movement of the guides 2 in an upward direction so as to change the configuration of the louvers assembly 10 from an open state to a closed state. The rod 5 is also configured to be triggered either manually or by any suitable device capable of contacting the rod 5, therefore, forcing the whole structure to move upward.

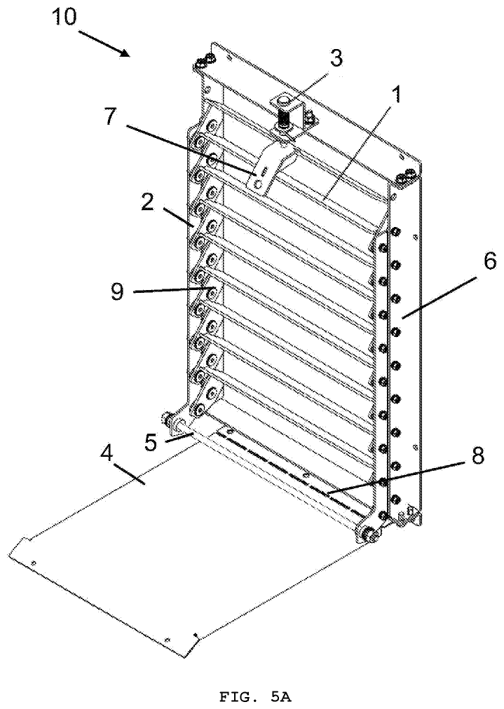

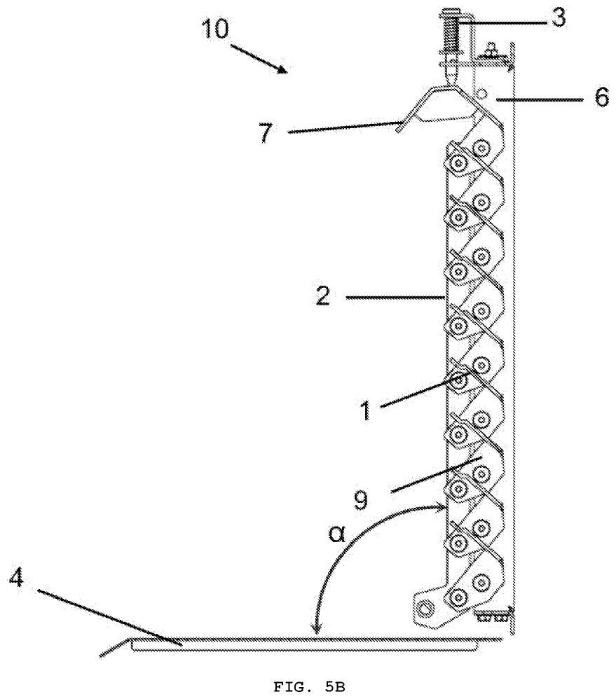

FIGS. 5A to 8B present different embodiments of the louvers assembly 10 including a flap 4 located underneath the one or more louvers 1 and the rod 5. The flap 4 is configured to act as a driving means working together with the rod 5 in order to close the louvers 1, preventing flames and debris from escaping through the ventilation input and cause serious damage to nearby people and equipment. Due to the load caused by the shock wave force produced from the arc fault explosion and arising from a 90 region 70, as exemplary demonstrated in FIG. 2, the flap 4 will be deformed and rotate around a weak line 8 positioned in a region substantially away from the center of the flap 4 and in the vicinity of an edge, serving as a rotating axis. In other words, the flap 4 is arranged to transfer movement to the rod 5, acting as a drive using the arc fault explosion energy shock wave. Additionally, the flap 4 is also a mechanism to redirect the flow of the expansion wave that occurs inside the enclosure to another region of the system, for instance, the ventilation output 60. Furthermore, while redirecting the flow of the expansion wave, the flap 4 also serves as an additional protection implement since the flames and debris will first hit the bottom portion of the flap 4 before hitting the louvers 1. This greatly decreases the amount of debris that can escape through the louvers 1.

Furthermore, the flap 4 is also used as additional reinforcement, together with the spring system 3 and the locking mechanism 7, to secure and maintain the louvers 1 in a closed state, when an arc fault event occurs.

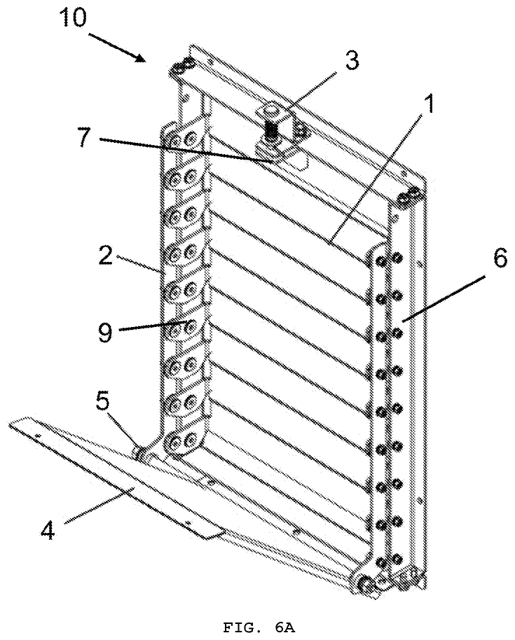

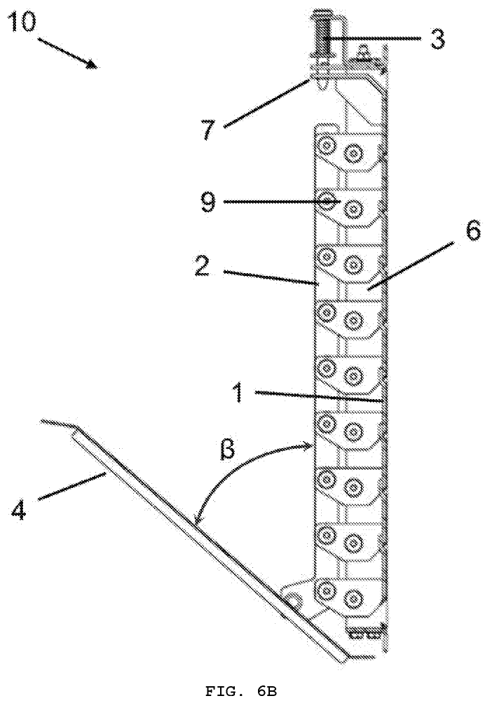

Specifically, FIGS. 5A and 5B show the louvers assembly 10 with a horizontal flap 4 when the louvers 1 are in an open state. Consequently, FIGS. 6A and 6B present the louvers assembly 10 with the horizontal flap 4 in a deformed configuration when the louvers 1 are in a closed state.

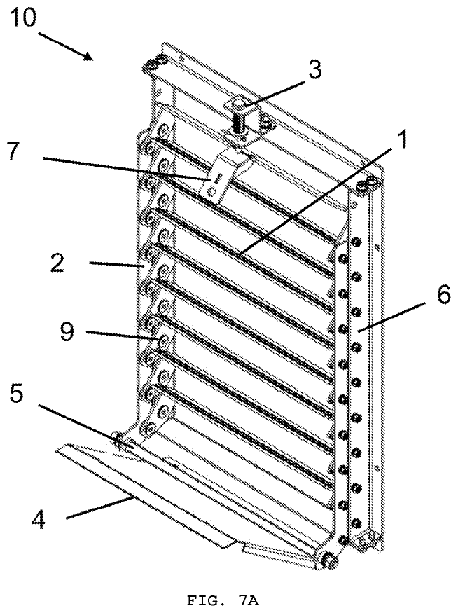

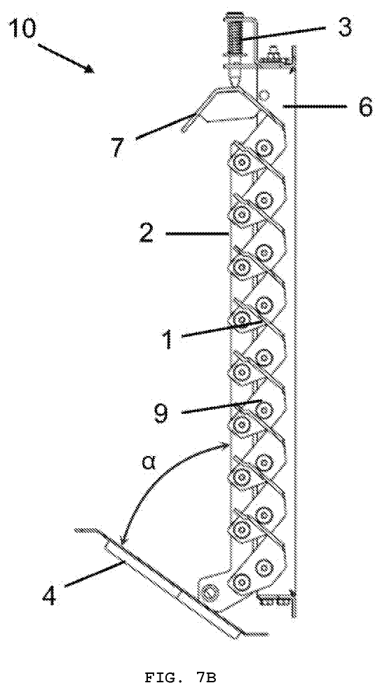

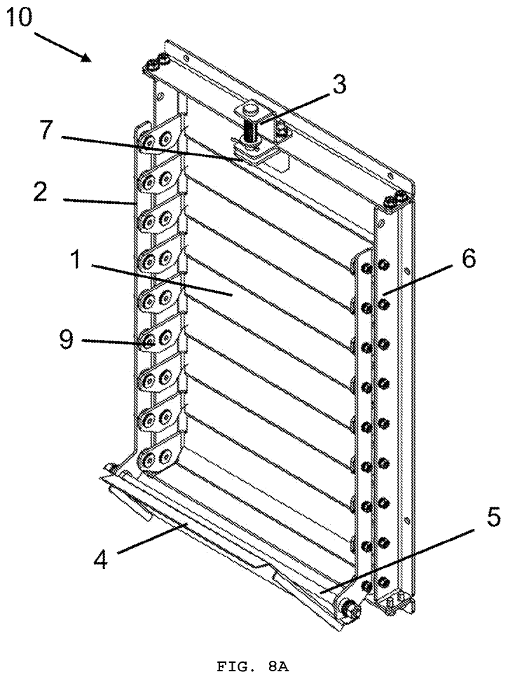

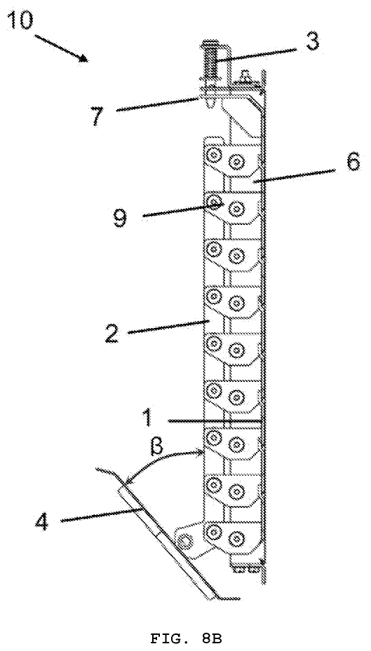

In an alternative embodiment to FIGS. 5A-6B of the present invention, FIGS. 7A and 7B show the louvers assembly 10 with an inclined flap 4 when the louvers 1 are in an open state, whereas FIGS. 8A and 8B show the louvers assembly 10 with the inclined flap 4 in a deformed configuration when the louvers 1 are in a closed state. Inclined flaps 4 are to be used in situations that demand a specific ventilation direction or an increase in insulation distances, for example.

According to the present invention, the flap opening angle α of FIGS. 5B and 7B can vary between about 0 to about 180 degrees (when the flap 4 is parallel to the horizontal plane) to any degree between about 0 to about 180 degrees in relation to a vertical axis, whereas the flap closing angle β of FIGS. 6B and 8B is sufficient to close the louvers safely.

As can be inferred from the closed state embodiments of FIGS. 6A, 6B, 8A and 8B, the flap 4 also secures the rod 5 in position when the flap 4 is plastically deformed. Hence, both the flap 4 and the spring system 3 are features that ensure that the one or more louvers 1 do not return to the open state by the gravity force, which could cause some fire or debris leakage.

In addition, although the aforementioned embodiments have been described, assuming, by way of example, that the ventilation system was built in an upper region of the electrical enclosure 100, the present invention also provides that the louvers assembly 10 with the flap 4 can be mounted in a lower region of the electrical enclosure 100. In this embodiment, the entire assembly would be placed upside down, in an inverted position, with the flap 4 positioned above the rod 5 and louvers 1 to serve as a shield for a shock wave coming from an upstream region of the enclosure 100. Thus, the operating principle and technical features are maintained in relation to what was described above. In sum, the louvers assembly of the present invention can be mounted in a regular or inverted position, in any side interface of the electrical enclosure.

Further, the components of the louvers assembly described above can be made of any material, including metal alloy, polymers, ceramics, combinations thereof, or any other material suitable for working at high temperature and sustain the shock wave.

Using a metal alloy can use any superficial treatment or coating, as some examples, galvanization, zinc plating, etc, suitable for working at high temperature.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A louvers assembly applied to a ventilation system of an electrical enclosure, the louvers assembly comprising:
a fixed frame attached to a ventilation aperture in the wall of the ventilation input region;
one or more louvers, wherein each end of each louver is attached to a connecting piece that connects the fixed frame to a guide of the louvers assembly;
a spring system attached to the top side of the frame;
a locking mechanism arranged at the uppermost louver of the one or more louvers; and
a flap arranged to transfer movement to a rod which is connected at each end to one of the guides;
the flap being located underneath the one or more louvers and the rod, wherein the flap is configured to act as a driving means when using the arc fault explosion energy shock wave, working together with the rod in order to close the louvers.

2. The louvers assembly of claim 1, wherein the guide is axially movable to allow the one or more louvers to simultaneously rotate altogether upon changing from an open state to a closed state.

3. The louvers assembly of claim 1, wherein the spring system includes a pin placed within a spring, the pin being connected at its upper portion to a first shaped plate with a foldable profile and at a lower portion to a second shaped plate such that the pin passes through concentric holes of the plates.

4. The louvers assembly of claim 3, wherein the plates form a U-shaped profile securing the pin, and the spring being contained between the first shaped plate and the second shaped plate.

5. The louvers assembly of claim 3, wherein the lower portion of the pin is provided with a protrusion having a rounded tip configured to pass through the holes of the second shaped plate and the locking mechanism.

6. The louvers assembly of claim 3, wherein when the louvers move from the open state to the closed state, it will activate the spring movement and the spring will recoil and then return to its extended configuration when the rounded tip of the pin reaches a groove in the locking mechanism before the protrusion passes through the hole located in the distal portion of the locking mechanism.

7. The louvers assembly of claim 1, wherein the rod is configured to trigger the movement of the guides in an upward direction so as to change the configuration of the louvers assembly from an open state to a closed state.

8. The louvers assembly of claim 1, wherein the spring system, the locking mechanism, and the flap acting together are configured to secure and maintain the louvers in a closed state.

9. The louvers assembly of claim 1, wherein the flap is configured to deform in response to a shock wave force arising from a downstream region and rotate around a weak line positioned in a region substantially away from the center of the flap and in the vicinity of an edge.

10. The louvers assembly of claim 1, wherein the flap redirects the flow of the expansion wave that occurs inside the enclosure to another region of the ventilation system when the outcomes of the arc fault explosion hit the bottom portion of the flap.

11. The louvers assembly of claim 1, wherein the flap is a horizontal flap or an inclined flap.

12. The louvers assembly of claim 11, wherein the flap opening angle can vary from about 0 degrees to about 180 degrees in relation to a vertical axis, and the flap closing angle is sufficient to close the louvers safely.

13. The louvers assembly of claim 1, wherein the flap secures the rod in position when the flap is plastically deformed.

14. The louvers assembly of claim 1, wherein the louvers assembly is further configured to be mounted in a regular or inverted position in any side interface of the electrical enclosure.

15. The louvers assembly of claim 1, wherein the louvers assembly, spring system and flap can be made of any material, including metal alloy, polymers, ceramics, combinations thereof, or any other material suitable for working at high temperature and sustain the shock wave.

16. A ventilation system for use in an electrical enclosure, wherein the ventilation system comprises the louvers assembly of claim 1.

17. An electrical enclosure, comprising the louvers assembly of claim 1.
